(19) United States
(12) Patent Application Publication
(10) Pub. No.: US 2011/0122912 A1
(43) Pub. Date: May 26, 2011

(54) OPTICAL TRANSMITTERS FOR MM-WAVE ROF SYSTEMS

(76) Inventors: Seldon D. Benjamin, Painted Post, NY (US); Davide D. Fortusini, Ithaca, NY (US); Anthony Ng'oma, Painted Post, NY (US); Michael Sauer, Corning, NY (US)

(21) Appl. No.: 12/712,758

(22) Filed: Feb. 25, 2010

Related U.S. Application Data
(60) Provisional application No. 61/263,124, filed on Nov. 20, 2009.

(51) Int. Cl. H01S 5/183; H01S 5/50

(52) U.S. Cl. 372/50.124; 372/50.22

(57) ABSTRACT

Optical transmitters for radio over fiber systems are disclosed. More particularly, the optical transmitters include optically-injection-locked vertical cavity surface-emitting laser devices (OIL VCSELS). The transmitters include a master laser, at least one slave laser injection-locked by the master laser, and an equalizer/filter unit that enables the ratio of the carrier power to the sideband power in the output signal of the transmitter to be varied and optimized independently of the injection ratio of the transmitter.

### PRIORITY APPLICATION

This application claims the benefit of U.S. Provisional Application No. 61/263,124, filed Nov. 20, 2009, the entire contents of which are incorporated by reference.

### BACKGROUND

1. Technical Field

The disclosure relates to optical transmission devices, and more particularly to optically injection-locked semiconductor laser devices for high speed optical transmission.

2. Technical Background

Optically injection-locked (OIL) semiconductor lasers are promising optical sources for high-speed optical transmission because they exhibit enhanced frequency response, and are therefore suitable for direct modulation. The enhanced frequency response is of particular importance for multi-Gbps fiber-wireless systems operating at millimeter wave frequencies, such as 60 GHz. In optical injection-locking, the optical output from a master laser is injected into a slave laser. Under particular conditions, the slave laser is “locked” to the master, i.e., the laser emission of the slave laser is locked in optical frequency and phase to the optical field of the master laser. Under these conditions, enhancement of the slave laser's characteristics can be obtained. A particularly interesting class of low-cost OIL sources is represented by OIL Vertical-Cavity Surface-Emitting Lasers (VCSELs), in which the slave laser is a VCSEL.

For a given slave laser, the frequency response depends on the OIL condition, which is characterized by two parameters: 1) the frequency detuning (difference in optical frequency between the master laser and the free-running slave laser) and 2) the injection ratio (ratio of master laser optical power to slave laser optical power). With an appropriate choice of these parameters, the frequency response of the OIL VCSEL shows a resonance peak that enhances the response at high frequency. In such a condition, the frequency response of the VCSEL can be tuned to low-pass or bandpass at a higher frequency. Moreover, the OIL VCSEL produces a single-sideband (SSB) modulation. The bandpass frequency response and the single-sideband modulation make the OIL VCSEL particularly suitable for use in radio-over-fiber (RoF) systems as an optical transmitter to generate an optical signal that can be transported to a remote antenna unit by means of an optical fiber.

One important drawback of known OIL VCSEL devices is that the attainable modulation depth (i.e., the ratio between the modulated signal power and the optical carrier power) is very small. This drawback arises from the fact that the optical output of the OIL VCSEL is spatially and spectrally coincident with the master laser's optical power, which is reflected by the VCSEL itself. The reflected master optical power is unmodulated, and it has substantially higher power than the modulated power emitted by the VCSEL. Consequently, the resulting optical signal consists of a very strong optical carrier and a much weaker modulated sideband. In general, weakly modulated optical signals lead to poor link efficiency because the imbalance between the optical carrier and the modulated sideband leads to a poor signal-to-noise ratio (SNR) of the detected electrical/RF signal, thus causing a high BER (bit error rate). It has been established that the best link efficiency is often obtained when the power in the carrier and the sideband(s) are approximately equal.

In Mach-Zehnder modulated systems, which are the most widely employed RoF systems for high frequency operation, the relative optical powers between the carrier and the sideband(s) are often controlled by tuning the modulator bias voltage. However, in OIL devices, this limitation cannot be overcome by reducing the power of the master laser or increasing the output power of the VCSEL, because doing so would modify the injection ratio away from the value necessary to obtain the desired frequency response.

In view of the above, it is desirable to provide OIL VCSEL optical transmission devices that optimize the ratio of optical carrier power to slave laser sideband power without changing the injection ratio of the devices.

### SUMMARY

One embodiment is an optical transmission device comprising a master laser configured to generate a master signal, a VCSEL configured for optical injection locking by the master laser, and an equalizer unit. The VCSEL is configured to generate a VCSEL output signal comprising a carrier component and a modulated sideband component. The equalizer unit is configured to receive the VCSEL output signal and output an equalized output signal having a reduced ratio of carrier component power to modulated sideband component power in comparison to the VCSEL output signal.

Another embodiment is an optical transmission device comprising a master laser configured to generate a master signal, a first VCSEL configured for optical injection locking by the master laser, a first three-port optical filter, a second VCSEL configured for optical injection locking by the master laser, and a second three-port optical filter. The first VCSEL is configured to generate a first VCSEL output signal comprising a first carrier component and a first modulated sideband component. The first three-port optical filter is configured to receive the first VCSEL output signal from the first VCSEL, separate the first carrier component and the first modulated sideband component, and separately transmit the first carrier component and the first modulated sideband component. The second VCSEL is configured to receive the first carrier component from the first three-port optical filter and generate a second VCSEL output signal comprising a second carrier component and a second modulated sideband component. The second three-port optical filter is configured to receive the second VCSEL output signal from the second VCSEL, separate the second carrier component and the second modulated sideband component, and separately transmit the second carrier component and the second modulated sideband component.

A further embodiment is an optical transmission method comprising injection locking a VCSEL by a master laser, operating the VCSEL to generate a VCSEL output signal comprising a carrier component and a modulated sideband component, transmitting the VCSEL output signal to an equalizer unit, forming an equalized output signal in the equalizer unit, and outputting the equalized output signal. The equalized output signal comprises a reduced ratio of carrier component power to modulated sideband component power in comparison to the VCSEL output signal.

A further embodiment is an optical transmission method comprising: injection locking a first VCSEL by a master laser; operating the first VCSEL to generate a first VCSEL output signal comprising a first carrier component and a first modulated sideband component; routing the first VCSEL output signal to a first three-port optical filter; separating the first carrier component and the first modulated sideband component with the first three-port optical filter; and separately transmitting the first carrier component and the first modulated sideband component with the first three-port optical filter. The method further comprises: injection locking a second VCSEL using the first carrier component; operating the second VCSEL to generate a second VCSEL output signal comprising a second carrier component and a second modulated sideband component; routing the second VCSEL output signal to a second three-port optical filter; separating the second carrier component and the second modulated sideband component with the second three-port optical filter; and separately transmitting the second carrier component and the second modulated sideband component from the second three-port optical filter.

The devices and methods disclosed herein enable higher optical link efficiency, higher spectral efficiency, higher bit rate, extended RoF links and longer wireless transmission distances in optical transmission systems. Additionally, the disclosed devices and methods provide relatively low cost ways to achieve the aforementioned attributes.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The drawings illustrate one or more embodiment(s), and together with the description serve to explain principles and operation of the various embodiments.

### BRIEF DESCRIPTION OF THE DRAWINGS

FIG. 1 is a schematic representation of an optical transmission device according to one embodiment, including an optical circulator configured to route the output of a master laser to a slave laser and route the output of the slave laser to an optical transmission channel, and including an optical filter between the optical circulator and the optical transmission channel;

FIG. 2 is a schematic representation of an optical transmission device according to another embodiment similar to the embodiment of FIG. 1, but including an optical amplifier between the optical filter and the transmission channel;

FIG. 3 is a schematic representation of an optical transmission device according to another embodiment, including two optical filters and a variable optical attenuator configured to provide a variable optical loss for the carrier component of an optical signal output by the device;

FIG. 4 is a schematic representation of an optical transmission device according to another embodiment, including an optical filter configured to route the output of a master laser to a slave laser and route the output of the slave laser to an optical transmission channel;

FIG. 5 is a schematic representation of an optical transmission device according to another embodiment similar to the embodiment of FIG. 4 and including an optical isolator configured to protect the master laser from a reflected carrier component of the output from the master laser;

FIG. 6 is a schematic representation of an optical transmission device according to another embodiment, in which the device is configured to injection lock a first slave laser and a second slave laser by reusing the optical carrier power emitted by a first optical filter as master power for the second slave laser;

FIG. 7 is a schematic representation of an optical transmission device according to another embodiment, including two optical filters and an amplifier configured to amplify a sideband component of an optical signal output by a slave laser;

FIG. 8 is a schematic representation of a conventional experimental OIL VCSEL setup;

FIG. 9 shows frequency response plots for the experimental setup of FIG. 8 with the VCSEL operating in free-running and OIL modes;

FIG. 10 shows a plot of the optical spectra of the experimental setup of FIG. 8 modulated with constant wavelength RF carriers at different frequencies;

FIG. 11 shows the frequency response of an OIL-RoF link established by the experimental setup of FIG. 8 for different fiber lengths;

FIG. 12 shows curves of bit error rate (BER) versus received optical power for the experimental setup of FIG. 8 operating in injection-locked mode with 2 Gbps amplitude shift key (ASK) baseband modulation on a 60.5 GHz carrier;

FIG. 13 shows the optical spectrum of the experimental setup of FIG. 8 modulated with a 2 Gbps ASK signal at 60.5 GHz;

FIG. 14 is a schematic representation of a novel experimental OIL VCSEL setup configured to filter/equalize the output of an OIL VCSEL;

FIG. 15 shows the optical spectrum of the experimental setup of FIG. 14 modulated with a 2 Gbps ASK signal at 60.5 GHz;

FIG. 16 shows frequency response plots of the experimental setup of FIG. 14 with the VCSEL operating in free-running and OIL modes;

FIG. 17 shows the electrical spectrum of a recovered baseband signal from the experimental setup of FIG. 14, employing direct modulation, after downconversion at a wireless receiver;

FIG. 18 shows curves of BER versus received optical power for the experimental setups of FIG. 8 (without filtering/equalization) and FIG. 14 (with filtering/equalization) modulated with a 2 Gbps ASK signal at 60.5 GHz;

FIGS. 19 and 20 show curves of BER versus received optical power for the experimental setup of FIG. 14 modulated with a 2 Gbps ASK signal at 60.5 GHz and a 3 Gbps ASK signal at 60.5 GHz, respectively.

FIG. 21 shows eye diagrams of received ASK data before and after transmission over 20 km of standard single-mode fiber and 3 m wireless distance;

FIG. 22 shows the electrical spectrum of a recovered RF signal from the experimental setup of FIG. 14, employing 2 Gbps QPSK modulation at a sub-carrier frequency of 1.5 GHz;

FIG. 23 shows signal-to-noise ratio (SNR) performance of the experimental setup of FIG. 14, modulated with 2 Gbps QPSK data, after transmission over up-to 20 km of standard single-mode fiber and 3 m wireless distance; and

FIG. 24 shows constellation diagrams for the experimental setup of FIG. 14, modulated with 2 Gbps QPSK data, after transmission over 20 km of standard single-mode fiber and 3 m wireless distance.

### DETAILED DESCRIPTION

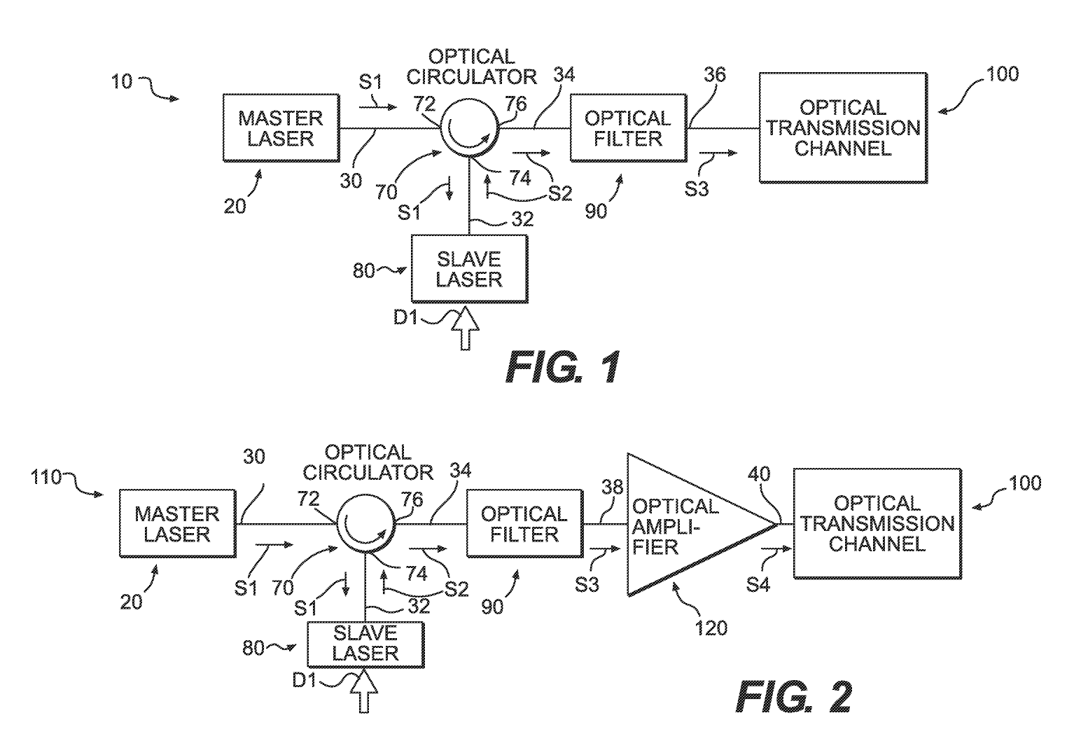

Reference will now be made in detail to the present preferred embodiments, examples of which are illustrated in the accompanying drawings. Whenever possible, the same reference numerals and characters will be used throughout the drawings to refer to the same or like parts. The disclosure is directed to optical transmission devices for radio-over-fiber (RoF) systems and particularly for multi-Gbps fiber-wireless systems operating at millimeter wave frequencies, such as 60 GHz. One embodiment of an optical transmission device is shown in FIG. 1, and is designated generally throughout by the reference numeral 10.

As shown in FIG. 1, the optical transmission device 10 includes a master laser 20, an optical circulator 70 coupled to the master laser 20 by an optical link 30, a slave laser 80 coupled to the optical circulator 70 by an optical link 32, and a filter unit or equalizer unit 90 coupled to the optical circulator 70 by an optical link 34. The filter unit/equalizer unit 90 is coupled to an optical transmission channel 100 by an optical link 36. The optical links 30, 32, 34, 36 can be optical fibers or other optical connections such as, for example, optical waveguides or free-space optical connections.

The master laser 20 can be a high power, continuous-wave (CW) distributed feedback laser, for example. Suitable devices for the master laser 20 include, but are not limited to, EM4 model AA1401 manufactured by EM4 Incorporated. It should be understood, however, that other laser types and models can be used. The master laser 20 is configured to output a master optical signal S1, which includes an unmodulated optical carrier signal component.

The slave laser 80 can be, for example, a vertical cavity surface-emitting laser (VCSEL), such as a 1540 nm single mode buried tunnel junction (BTJ) VCSEL with a maximum power output of about 3 mW and 70% coupling efficiency to lensed fiber. The slave laser 80 is injection-locked by the master laser 20, such that the slave laser 80 is configured to output an optical signal S2 that is locked in frequency and phase to the carrier signal S1 of the master laser 20. The slave laser 80 is modulated such that the signal S2 is a modulated signal having a carrier signal component and a single sideband signal component. The slave laser 80 can be modulated by a data stream D1, which can include amplitude shift key (ASK) modulated data, quadrature phase key modulated data (QPSK), or orthogonal frequency division multiplexing (OFDM), for example. Other modulation formats are possible, as well.

The optical circulator 70 includes a first port 72 in optical communication with the master laser 20 via the optical link 30, a second port 74 in optical communication with the slave laser 80 via the optical link 32 and a third port 76 in optical communication with the filter unit/equalizer unit 90 via the optical link 34. As illustrated in FIG. 1, the optical circulator 70 is configured to route the signal S1 of the master laser 20 to the slave laser 80 and to route the output signal S2 of the slave laser 80 to the filter unit/equalizer unit 90. The optical circulator 70 can be a three-port optical circulator, such as JDSU model CIR-330011000 manufactured by JDS Uniphase Corporation, for example.

The filter unit/equalizer unit 90 can be an optical bandpass filter having a wavelength dependent transmission. Examples of suitable bandpass filters are JDSU models TB9226 or MTBF-A1CS0 manufactured by JDS Uniphase Corporation, however other bandpass filters can be used. The bandpass filter 90 is configured to attenuate the carrier signal component and transmit an equalized output signal S3 to the optical transmission channel 100. In other words, the filter 90 is configured such that the wavelength of the sideband signal component is located in the passband of the filter 90. The output signal S3 includes an attenuated carrier signal component (high insertion loss through the filter 90) and a less attenuated or substantially unattenuated sideband signal component (minimal insertion loss through the filter 90). The output signal S3 is said to be an “equalized” signal because the ratio of optical power of the carrier signal component to optical power of the sideband signal component in signal S3 is reduced in comparison to the signal S2 output by the slave laser 80. Generally speaking, it is desirable for the ratio of the carrier signal component power to the sideband signal component power in the signal S3 to be close to 0 dB (i.e., roughly equal power in the carrier and sideband signal components), and the filter 90 can be tuned accordingly. One method of tuning the filter 90 is to place the carrier signal component of the signal S2 on one of the edges of the response curve of the filter 90, and then adjust the power of the carrier signal component upwards or downwards by tuning the center frequency of the filter 90 on the left or right. If the transmission characteristics of the filter 90 are roughly uniform over its passband, then the power of the modulated sideband will remain constant during filter tuning.

In operation of the device 10, the master laser 10 generates the master signal S1, which is routed through the optical circulator 70 to the slave laser 80. The slave laser 80 is injection-locked by the master laser 20, and as a result outputs the modulated signal S2 including the carrier signal component from the master laser 20 and a modulation sideband signal component. The signal S2 is routed through the optical circulator 70 to the filter unit/equalizer unit 90. The filter unit/equalizer unit 90 attenuates the carrier signal component to a greater degree than it attenuates the modulation sideband signal component or, alternatively, attenuates the carrier signal component while passing the modulation sideband signal component substantially unattenuated to form the equalized output signal S3. The output signal S3, including the attenuated carrier component and the less attenuated/substantially unattenuated sideband signal component, is transmitted to the optical transmission channel 100.

Although the filter unit/equalizer unit 90 is described as being a bandpass filter, it should be understood that other types of filters such as low-pass filters and band-stop filters (e.g. fiber bragg grating filters (FBG)) can be used.

Another embodiment of an optical transmission device is shown in FIG. 2, and is designated by the reference numeral 110. The device 110 is similar to the device 10 of FIG. 1, with exception that, instead of the filter unit/equalizer unit 90 being coupled directly to the optical transmission channel 100, the device 110 includes an optical amplifier 120 coupled to the filter unit/equalizer unit 90 by an optical link 38 and coupled to the optical transmission channel 100 by an optical link 40. The optical links 38, 40 can be optical fibers or other optical connections such as, for example, optical waveguides or free-space optical connections.

The optical amplifier 120 can be an Erbium-doped waveguide amplifier (EDFA), for example, such as Oclaro models PureGain PG1000 or PureGain PG1600 manufactured by Oclaro, Incorporated. However, other types of amplifiers can be used. The optical amplifier 120 is configured to amplify the equalized output signal S3 from the filter unit/equalizer unit 90 and transmit an amplified, equalized output signal S4 to the optical transmission channel 100. By transmitting the amplified, equalized output signal S4, the device 110 provides increased signal-to-noise (SNR) ratios and enables a longer fiber and wireless transmission range, use of signal modulation formats with higher spectral efficiency (e.g. QPSK) leading to higher bit rates in comparison to the embodiment of FIG. 1.

According to a variation of the embodiment of FIG. 2, the optical amplifier 120 can be configured to provide higher optical gain to the sideband signal component of the signal S3 than the optical gain provided to the carrier signal component of the signal S3. For example, the optical amplifier 120 can include a component that provides wavelength-dependent optical gain or wavelength-dependent optical loss. In such a variation, the optical amplifier 120 also performs the function of an optical filter, and the filter unit/equalizer unit 90 can therefore be eliminated.

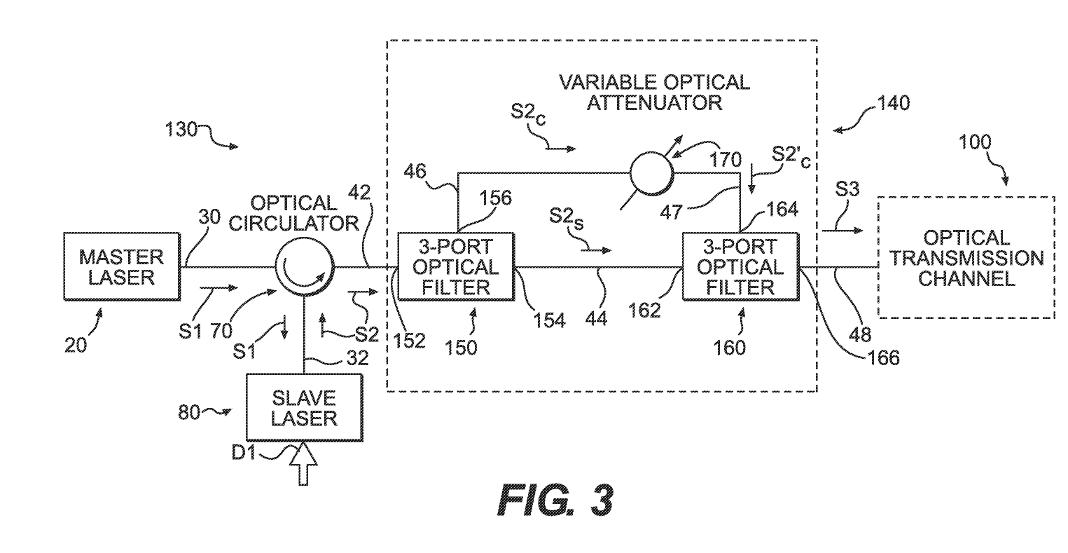

Another embodiment of an optical transmission device is shown in FIG. 3, and is designated by the reference numeral 130. The device 130 is similar to the device 10 of FIG. 1, except that the device 130 includes a filter unit/equalizer unit 140 instead of the filter unit/equalizer unit 90. The filter unit/equalizer unit 140 is coupled to the optical circulator 70 by an optical link 42 and coupled to the optical transmission channel 100 by an optical link 48. The filter unit/equalizer unit 140 includes a first three-port optical filter 150, a second three-port optical filter 160 and a variable optical attenuator 170. The three-port optical filters 150, 160 can be JDSU model DWS-1Fxxx3L20 manufactured by JDS Uniphase Corporation, for example. The variable optical attenuator 170 can be JDSU MVOA-A2SS0-M100-MFA manufactured by JDS Uniphase Corporation, for example. However, other types of filters and attenuators can be used.

The first three-port optical filter 150 includes a first port 152 coupled to the optical circulator 70 by the optical link 42, a second port 154 coupled to the second three-port optical filter 160 by the optical link 44, and a third port 156 coupled to the variable optical attenuator 170 by an optical link 46. The second three-port optical filter 160 includes a first port 162 coupled to the second port 154 of the first three-port optical filter 150 by the optical link 44, a second port 164 coupled to the variable optical attenuator 170 by an optical link 47, and a third port 166 coupled to the optical transmission channel 100 by the optical link 48. The optical links 42, 44, 46, 47, 48 can be optical fibers or other optical connections such as, for example, optical waveguides or free-space optical connections.

The first three-port optical filter 150 is configured to receive the signal S2 from the slave laser 80 through the first port 152 and separate the sideband signal component S2ₛ and the carrier signal component S2_{c} of the signal S2 from each other based on the difference in wavelength between the sideband signal component S2ₛ and the carrier signal component S2_{c}. The first three-port optical filter 150 is configured to output the sideband signal component S2ₛ and the carrier signal component S2_{c} from its second and third ports 154, 156, respectively, with minimal attenuation of the components S2ₛ, S2_{c}. The variable optical attenuator 170 is configured to attenuate the carrier signal component S2_{c} to form an attenuated carrier signal component S2_{c}′ and output the attenuated carrier signal component S2_{c}′. The second three-port optical filter 160 is configured to receive the sideband signal component S2ₛ and the attenuated carrier signal component S2_{c}′ through the first and second ports 162, 164, respectively, and combine the sideband signal component S2ₛ and the carrier signal component into a single, equalized output signal S3. The second three-port optical filter 160 is configured to output the signal S3 through the third port 166 to the optical link 48.

In operation of the device 130, the first optical filter 150 receives the signal S2 and filters the signal S2 such that the sideband signal component S2ₛ and the carrier signal component S2_{c} are separated from each other in the filter 150 with little or no attenuation of both components S2ₛ, S2_{c}. The first optical filter 150 then outputs the sideband signal component S2ₛ to the second three-port optical filter 160 and outputs the carrier signal component S2_{c} to the variable optical attenuator 170. The variable optical attenuator 170 then attenuates the carrier signal component S2_{c} to form the attenuated carrier signal component S2_{c}′ and outputs the attenuated carrier signal component S2_{c}′ to the second three-port optical filter 160. The second three-port optical filter 160 then combines the sideband signal component S2ₛ and the attenuated carrier signal component S2_{c}′ to form the equalized output signal S3 and outputs the signal S3 to the optical transmission channel 100 via the optical link 48. The amount of attenuation carried out by the variable optical attenuator 170 can be varied based on the desired ratio of carrier signal component power to sideband signal component power in the signal S3.

According to a variation of the embodiment of FIG. 3, the second three-port optical filter 160 can be replaced with a three-port optical power coupler configured to receive the sideband signal component S2ₛ and the attenuated carrier signal component S2_{c}′ from the first three-port optical filter 150 and the variable optical attenuator 170, respectively, and combine the sideband signal component S2ₛ and the attenuated carrier signal component S2_{c}′ to form the equalized output signal S3. An example of a suitable three-port optical power coupler is JDSU model FFCHCKS1AB100 manufactured by JDS Uniphase Corporation, for example.

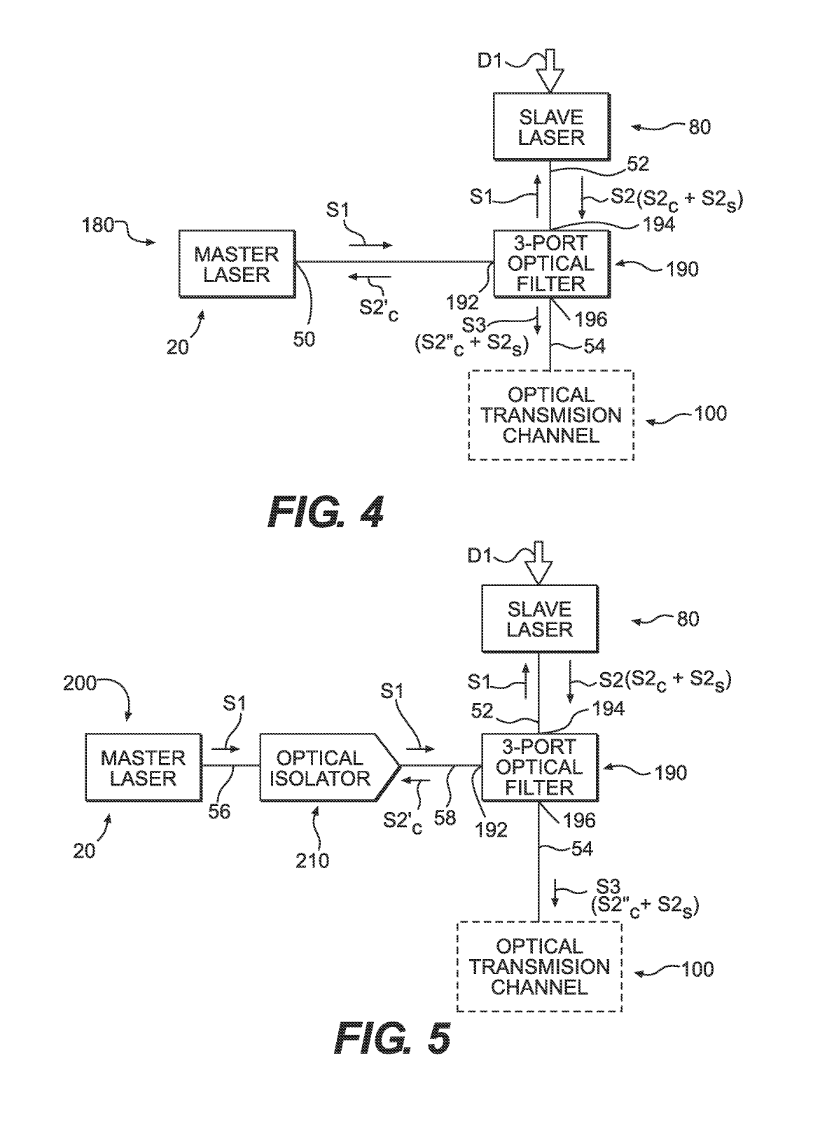

Another embodiment of an optical transmission device is shown in FIG. 4, and is designated by the reference numeral 180. The device 180 includes a master laser 20, a filter unit/equalizer unit 190 coupled to the master laser 20 by an optical link 50, and a slave laser 80 coupled to the filter unit/equalizer unit 190 by an optical link 52. The filter unit/equalizer unit 190 is coupled to an optical transmission channel 100 by an optical link 54. The optical links 50, 52, 54 can be optical fibers or other optical connections such as, for example, optical waveguides or free-space optical connections.

The filter unit/equalizer unit 190 can be a three-port optical filter having a first port 192 coupled to the master laser 20 by the optical link 50, a second port 194 coupled to the slave laser 80 by the optical link 52, and a third port 196 coupled to the optical transmission channel 100 by the link 54. The three-port optical filter 190 can be an interference filter, such as JDSU model DWS-1Fxxx3L20 manufactured by JDS Uniphase Corporation, for example.

As in the previous embodiments, the master laser 20 is configured to output a signal S1 including a carrier signal component. The three-port optical filter 190 is configured such that light of the wavelength of the signal S1 can pass from the first port 192 to the second port 194 with low loss (insubstantial attenuation), and is therefore configured to route the signal S1 to the slave laser 80 with low loss. The slave laser 80 can therefore be injection-locked by the master laser 20, such that slave laser 80 is configured to output an optical signal S2 having a carrier signal component S2_{c} and a single sideband signal component S2ₛ. The three-port optical filter 190 is configured such that the sideband signal component of the signal S2ₛ can pass from the second port 194 to the third port 196 with low loss, and the carrier signal component S2_{c} can pass from the second port 194 to the third port 196 with high loss (at least partial attenuation) such that a large portion of the carrier signal component S2_{c}′ is reflected towards the master laser 20. Thus, the three-port optical filter 190 is configured to output an equalized output signal S3 to the optical transmission channel 100 through the optical link 54 including the sideband signal component S2ₛ of the signal S2 and a partially attenuated carrier signal component S2_{c}″ derived from the signal S2.

In operation of the device 180, the master laser 20 outputs the signal S1 to the three-port optical filter 190. The three-port optical filter 190 then routes the signal S1 to the slave laser 80, which, in response, outputs the signal S2 to the three-port optical filter 190. The three-port optical filter 190 then reflects the portion S2_{c}′ of the carrier signal component towards the master laser 20 through the first port 192 and outputs the equalized output signal S3, including the sideband signal component S2ₛ and the partially attenuated carrier signal component S2_{c}″, through the third port 196. Thus, it can be appreciated that the three-port optical filter 190 performs the functions of routing the signals S1, S2 and filtering the signal S2.

According to a variation of the embodiment of FIG. 4, the three-port optical filter 190 can be configured to absorb, rather than reflect, the portion S2_{c}′ of the carrier signal component S2_{c}.

Another embodiment of an optical transmission device is shown in FIG. 5, and is designated by the reference numeral 200. The device 200 is similar to the device 180 of FIG. 4, except that the device 200 includes an optical isolator 210 disposed in the pathway between the master laser 20 and the three-port optical filter 190 to protect the master laser 20 from the reflected portion of the carrier signal component S2_{c}′. Specifically, the optical isolator 210 can be coupled to the master laser 20 by an optical link 56 and coupled to the first port 192 of the three-port optical filter 190 by an optical link 58. The optical links 56, 58 can be optical fibers or other optical connections such as, for example, optical waveguides or free-space optical connections. Alternatively, the optical isolator 210 can be integrally formed with the master laser 20.

The optical isolator 210 is configured to absorb the backward travelling carrier signal component S2_{c} to prevent the reflected portion of the carrier signal component S2_{c}′ from interfering with the operation of the master laser 20 or even damaging it. The optical isolator 210 can be Photop model KISO-S-A-250S-1550-NN manufactured by Photop Technologies, Incorporated, for example.

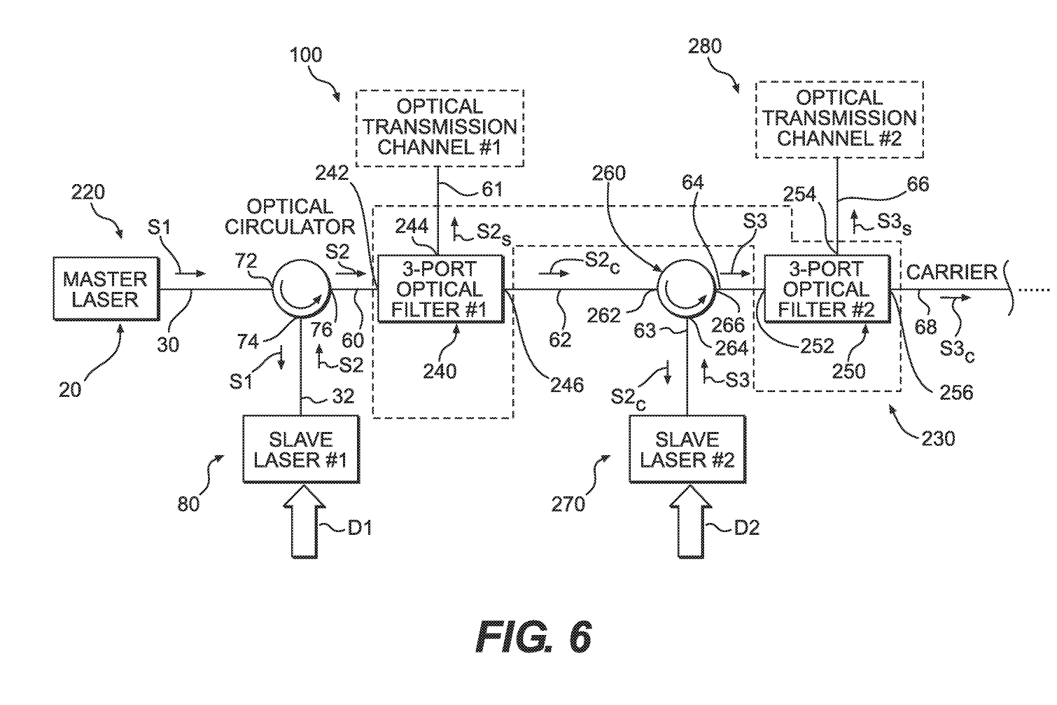

Another embodiment of an optical transmission device is shown in FIG. 6, and is designated by the reference numeral 220. The optical transmission device 220, similarly to the embodiment of FIG. 1, includes a master laser 20, an optical circulator 70 coupled to the master laser 20 by an optical link 30, and a first slave laser 80 coupled to the optical circulator 70 by an optical link 32. The device 220 includes a filter unit/equalizer unit 230 coupled to the first optical circulator 70 by an optical link 60, a second optical circulator 260 including a first port 262, a second port 264 and a third port 266, and coupled to the filter unit/equalizer unit 230 by optical links 62, 64, and a second slave laser 270 coupled to the second optical circulator 260 by an optical link 63. The filter unit/equalizer unit 230 is coupled to a first optical transmission channel 100 by an optical link 61 and a second optical transmission channel 280 by an optical link 66. The optical links 60, 61, 62, 63, 64, 66 can be optical fibers or other optical connections such as, for example, optical waveguides or free-space optical connections.

The filter unit/equalizer unit 230 includes a first three-port optical filter 240 having a first port 242 coupled to the third port 76 of the first optical circulator 70 by the optical link 60, a second port 244 coupled to the first optical transmission channel 100 by the optical link 61, and a third port 246 coupled to the first port 262 of the second optical circulator 260 by the optical link 62. The filter unit/equalizer unit 230 also includes a second three-port optical filter 250 having a first port 252 coupled to the third port 266 of the second optical circulator, a second port 254 coupled to the second optical transmission channel 280 by the optical link 66 and a third port 256 optionally connected to an additional device or component, such as another filter or circulator (not shown). The three-port optical filters 240, 250 are similar to the three-port optical filter 150 employed in the embodiment of FIG. 3.

The master laser 20 is configured to output a master optical signal S1 and the first slave laser 80 can be injection-locked by the master laser 20, such that the first slave laser 80 is configured to output an optical signal S2. The slave laser 80 is modulated by a first data stream D1 such that the signal S2 has a carrier signal component S2_{c} and a single sideband signal component S2ₛ including data from the first data stream D1. The first data stream D1 can include ASK modulated data, QPSK modulated data, or OFDM modulated data, for example.

The first three-port optical filter 240 is configured to receive the signal S2 from the first slave laser 80 through the first port 242 and separate the sideband signal component S2ₛ and the carrier signal component S2_{c} of the signal S2 from each other based on the difference in wavelength between the sideband signal component S2ₛ and the carrier signal component S2_{c}. The first three-port optical filter 240 is configured to output the sideband signal component S2ₛ and the carrier signal component S2_{c} from its second and third ports 244, 246, respectively, with minimal attenuation of the components S2ₛ, S2_{c}. The sideband signal component S2ₛ is transmitted to the first optical transmission channel 100 through the optical link 61.

The second optical circulator 260 is configured to route the carrier signal component S2_{c} to the second slave laser 270, and the second slave laser 270 therefore can also be injection-locked by the master laser 20. The second slave laser 270 is modulated by a data by a second data stream D2 such that the second slave laser 270 outputs a signal S3 having a carrier signal component S3_{c} and a single sideband signal component S3ₛ including data from the second data stream D2. The second data stream D2 can include ASK modulated data, QPSK modulated data, or OFDM modulated data, for example.

The second optical circulator 260 is configured to route the signal S3 to the second three-port optical filter 250. The second three-port optical filter 250 is configured to receive the signal S3 from the second slave laser 270 through the first port 252 and separate the sideband signal component S3ₛ and the carrier signal component S3_{c} of the signal S2 from each other based on the difference in wavelength between the sideband signal component S3ₛ and the carrier signal component S3_{c}. The second three-port optical filter 250 is configured to output the sideband signal component S3ₛ and the carrier signal component S3_{c} from its second and third ports 254, 256, respectively, with minimal attenuation of the components S3ₛ, S3_{c}. The sideband signal component S3ₛ is transmitted to the second optical transmission channel 280 through the optical link 66. The carrier signal component S3_{c} can optionally be transmitted to further components or devices (not shown) through the optical link 68.

In operation, the master laser 20 outputs the signal S1, which is routed through the first optical circulator 70 to the first slave laser 80. In response to the signal S1, the first slave laser 80 outputs the signal S2, which is routed through the first optical circulator 70 to the first three-port optical filter 240. The first three-port optical filter 240 separates the sideband signal component S2ₛ and the carrier signal component S2_{c} of the signal S2 from each other based on the difference in wavelength between the sideband signal component S2ₛ and the carrier signal component S2_{c}, and outputs the sideband signal component S2ₛ and the carrier signal component S2_{c} from its second and third ports 244, 246, respectively. There is minimal attenuation of the components S2ₛ, S2_{c} in the filter 240. The sideband signal component S2ₛ is transmitted to the first optical transmission channel 100 through the optical link 61, and the carrier signal component S2_{c} is transmitted to the second optical circulator 260. The second optical circulator 260 routes the carrier signal component S2_{c} to the second slave laser 270, and the second slave laser 270 is thereby injection-locked by the master laser 20. In response to the carrier signal component S2_{c}, the second slave laser 270 outputs the signal S3. The second optical circulator 260 routes the signal S3 from the second slave laser 270 to the second three-port optical filter 250, which separates the sideband signal component S3ₛ and the carrier signal component S3_{c} of the signal S3 from each other based on the difference in wavelength between the sideband signal component S3ₛ and the carrier signal component S3_{c}. The second three-port optical filter 250 then outputs the sideband signal component S3ₛ and the carrier signal component S3_{c} from its second and third ports 254, 256, respectively. There is minimal attenuation of the components S3ₛ, S3_{c} in the filter 250. The sideband signal component S3ₛ is transmitted to the second optical transmission channel 280 through the optical link 66, and the carrier signal component S2_{c} is optionally transmitted to other components or devices through the optical link 68.

It can be appreciated that the embodiment of FIG. 6 enables multiple slave lasers to be injection-locked by a single master laser and makes use of optical power that would otherwise be wasted. Specifically, the optical carrier power emitted by the first slave laser 80 is used as maser power for the second slave laser 270. Unlike conventional devices which include two slave lasers injection-locked by a master laser through a splitter, the power of the master laser 20 in the embodiment of FIG. 6 does not need to be two times the power necessary to injection-lock a single slave laser.

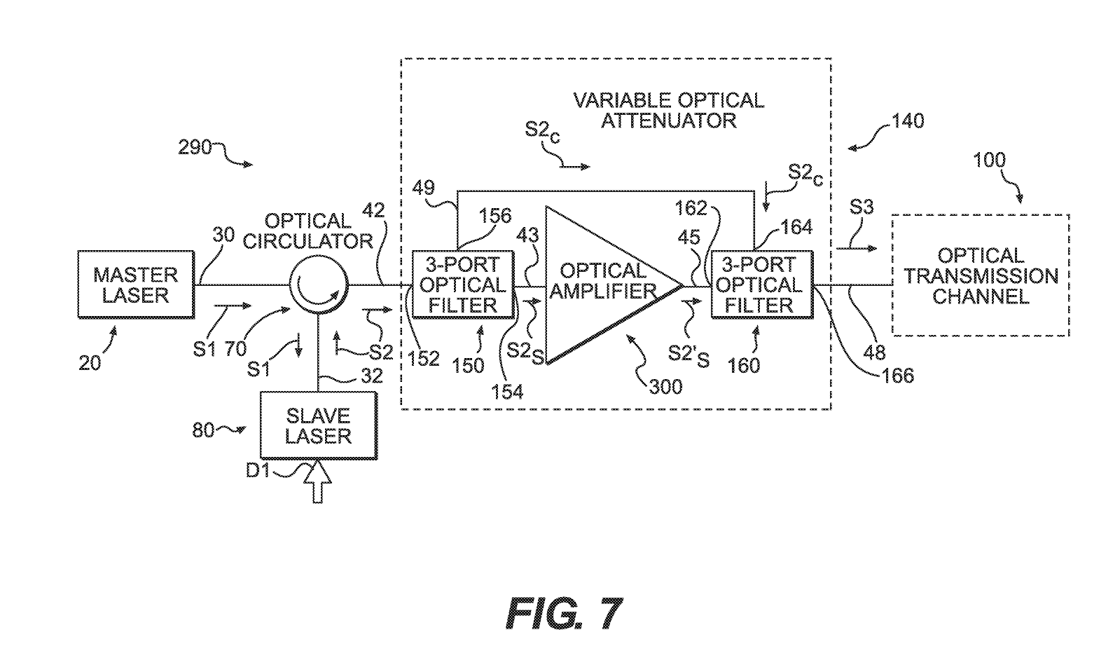

Another embodiment of an optical transmission device is shown in FIG. 7, and is designated by the reference numeral 290. The device 290 is similar to the device 130 of FIG. 3, with the exception that a variable gain optical amplifier 300 is located between the first and second three-port optical filters 150, 160, and the variable optical attenuator 170 is eliminated. An example of a suitable variable gain optical amplifier is Oclaro model PureGain PG2800 manufactured by Oclaro Incorporated, for example. Specifically, in this embodiment, the optical amplifier 300 is coupled to the second port 154 of the first three-port optical filter 150 by an optical link 43 (e.g., optical fiber, optical waveguide or free-space connection) and is coupled to the first port 162 of the second three-port optical filter 160 by an optical link 45 (e.g., optical fiber, optical waveguide or free-space connection). The third port 156 of the first three-port optical filter 150 is coupled to the second port 164 of the second three-port optical filter or optical power coupler 160 by an optical link 49 (e.g., optical fiber, optical waveguide or free-space connection).

The optical amplifier 300 is configured to amplify the sideband signal component S2ₛ to form an amplified sideband signal component S2ₛ′ and output the amplified sideband signal component S2ₛ′ to the second three-port optical filter 160. The amount of amplification can be adjusted as desired. The first three-port optical filter 150 is configured to output the carrier signal component S2_{c} to the second three-port optical filter 160. The second three-port optical filter or optical power coupler 160 is configured to combine the amplified sideband signal component S2ₛ′ and the carrier signal component S2_{c} to form an equalized output signal S3, and output the signal S3 to the optical transmission channel 100. Thus, the device 290 provides another way to use three-port optical filters to separate, equalize and recombine carrier and sideband signal components in an optical signal.

Various embodiments will be further clarified by the following examples.

### EXAMPLES

### Example 1

### Conventional Transmitter without Equalization of VCSEL Output

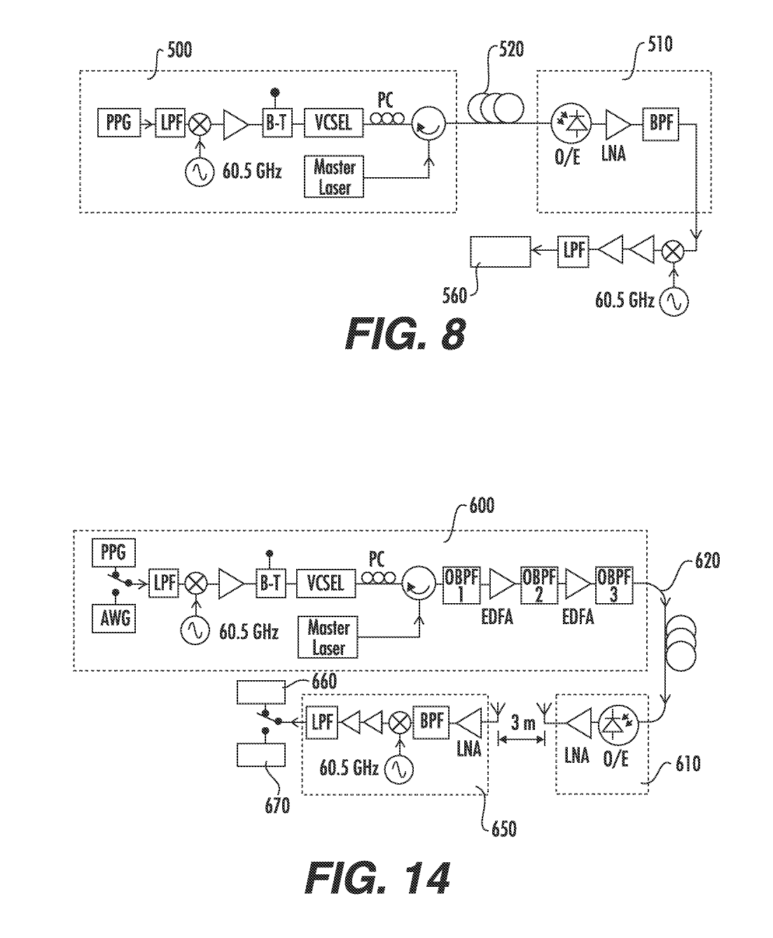

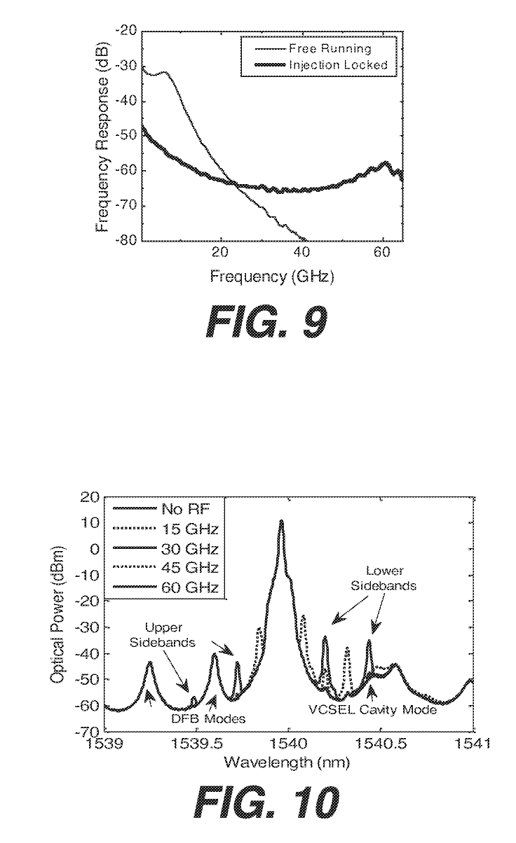

An experimental setup of a conventional OIL VCSEL RoF transmission system was constructed as shown in FIG. 8. In this setup, a Head-End Unit or HEU 500 was coupled to a remote antenna unit or RAU 510 by optical fiber 520. The HEU 500 consisted of a pulse pattern generator PPG, a low pass filter LPF, a bias T B-T, a slave VCSEL, a high-power Master Laser, and a custom-made one-step 60 GHz electrical up-converter. The remote antenna unit 510 included an optical-to electrical converter O/E, a low noise amplifier LNA, and a bandpass filter BPF. The signal from the remote antenna unit 510 was down-converted to baseband by a one-step 60 GHz down-converter, and fed into a bit error rate tester (BERT) 560. The VCSEL was a 1540 nm single-mode buried tunnel junction (BTJ) VCSEL with a maximum output power of ˜3 mW, and ˜70% coupling efficiency to a lensed fiber. The ML was a high-power Distributed Feedback (DFB) laser, which was operated in continuous wave (CW) mode. The VCSEL was injection locked by coupling a 40.7 mW optical signal from the high-power ML into the VCSEL via the circulator as shown. A polarization controller was used to maximize the injection ratio efficiency by matching the ML polarization to that of the VCSEL. The bias current of the VCSEL emitting ˜1 mW optical power was set at 4.7 mA. The ML was biased at 218.9 mA with an output power of 40.7 mW in order to achieve an optimized (flat) frequency response at 61 GHz as shown in FIG. 9, which illustrates VCSEL modulation bandwidth enhancement through optical injection locking.

To investigate the characteristics of SSB modulation under different signal frequencies, an un-modulated (CW) RF signal was applied to the VCSEL under OIL. The signal frequency was varied from 5 GHz to 65 GHz and the modulated optical signal observed on an Optical Spectrum Analyzer (OSA). FIG. 10 shows the optical spectra from the OIL transmitter modulated with single-tone (unmodulated) RF carriers at selected RF frequencies observed with the OSA resolution set to 0.02 nm. It can be seen that at lower modulation frequencies the two modulation sidebands were closer in intensity than at higher frequencies. For instance, at 15 GHz the power difference between the Upper Sideband (USB) and the Lower Sideband (LSB) was only 4.3 dB. This power difference grew to 10.7 at the RF modulation frequency of 30 GHz. At 60 GHz the power difference was even larger at 21.4 dB—with the LSB experiencing a significant amplification being near to the VCSEL cavity mode, and the USB being attenuated as shown.

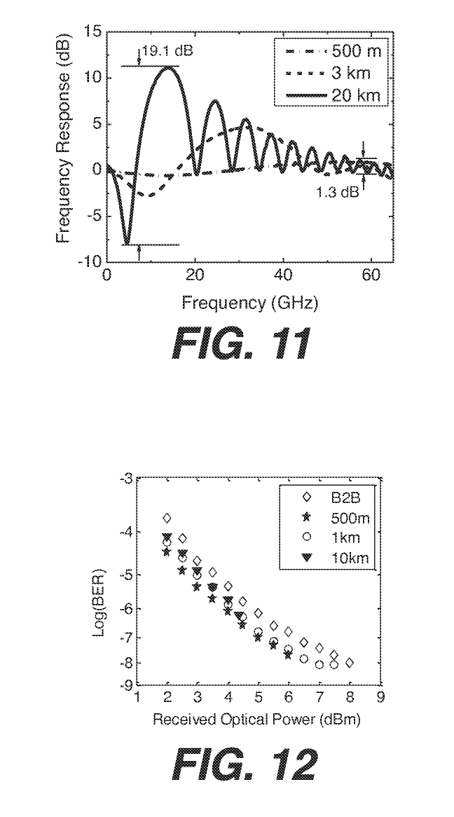

To examine the impact of fiber chromatic dispersion on RF signal fading, the transfer function of standard single-mode fiber at various lengths was measured with a Lightwave Component Analyzer. The fiber launch power was kept constant at +5.2 dBm in all cases, to ensure that Stimulated Brillioun Scattering (SBS) did not impact the results. The results are shown in FIG. 11, where the responses of various fiber lengths are normalized to the Back-to-Back (B2B) frequency response. Much larger signal amplitude swings were observed at lower frequencies than at higher frequencies. For instance, with the 20 km fiber transmission, the signal amplitude swing was 19.1 dB between 5 and 18 GHz, while it was just 1.3 dB around 60 GHz. The signal amplitude swings were caused by interfering modulation sidebands due to their relative phase variations caused by fiber's chromatic dispersion. This result implies that dispersion-induced fading in an intensity-modulation direct-detection (IMDD) RoF system employing an OIL-VCSEL is strongly frequency-dependent. Since chromatic dispersion is essentially constant over the RF frequencies considered, the reduced signal fading observed at 60 GHz is due to strong SSB modulation. This result is consistent with the result in FIG. 10, which shows that the modulated signal of an OIL VCSEL is essentially DSB at low frequencies becoming SSB only at higher (mm-wave) frequencies. This is an important bonus of using OIL for transmitting mm-wave signals since they are in fact more severely impacted by chromatic-dispersion induced signal fading than low-frequency signals.

The positive frequency response at lower frequencies observed in FIG. 11 is due to frequency modulation to intensity modulation (FM-IM) conversion of the chirp of the OIL VCSEL over the dispersive fiber.

IMDD RoF System at 60 GHz with Inherent Dispersion Tolerance

Using a simple one-step electrical up-converter, Pseudo Random Binary Sequence (PRBS) data at baseband was up-converted directly to a center frequency of 60.5 GHz in a single step. The PRBS pattern length was 2³¹−1. To further simplify the RoF system, both sidebands of the up-converted signal were returned for transmission. Therefore, the transmitted 60.5 GHz signal was DSB-modulated with the occupied 3 dB bandwidth of ˜4 GHz for the baseband data-rate of 2 Gbps.

The up-converted signal was amplified by a power amplifier (22 dB) to an average RF power of +0.5 dBm and fed into the VCSEL via a bias-T, resulting in direct intensity modulation of the VCSEL's optical signal at 60.5 GHz. The intensity-modulated optical signal was then transmitted over standard single-mode optical fibers of various lengths to the Remote Antenna Unit (RAU). Fiber launch power was set to +10 dBm.

At the RAU the transmitted optical signal was detected by a 70 GHz photodiode resulting in the generation of an ASK-modulated mm-wave signal at 60.5 GHz. The generated signal was amplified by a Low Noise Amplifier (LNA) with a gain of about 38 dB. After filtering in a 7 GHz BPF, the 60.5 GHz mm-wave signal was down-converted directly to baseband. Two cascaded low-frequency power amplifiers (24 dB+19 dB) amplified the recovered signal prior to analysis by the Error Detector (ED).

The measured BER for fiber spans of 0 km (B2B), 500 m, 1 km, and 10 km is shown in FIG. 12. It was observed that there was no significant difference in the system sensitivity for all fiber spans tested. For instance, at a BER of 1×10⁻⁵, the difference in optical power sensitivities for all the fiber spans was less than 0.5 dB. In a DSB-modulated RoF system, severe signal fading occurs at 60.5 GHz after 1 km fiber transmission. This results in serious ISI, a severely distorted eye diagram, and a very high BER. Therefore, this result shows that the 60 GHz RoF system employing an OIL-VCSEL for 2 Gbps ASK data modulation over single-mode fibers (various lengths) did not suffer the severe fiber chromatic dispersion-induced fading that limits the maximum fiber transmission distance of DSB-modulated systems to less than 1 km. This is attributed to the inherent strong SSB modulation present in OIL transmitters, as discussed above.

FIG. 12 reveals non-linearity in the RoF system at higher received optical powers exceeding +4 dBm leading to error flooring near the BER of 1×10⁻⁸. However, since the measured BER values are well below the FEC threshold, error free transmission is possible with FEC. Alternatively, simple linear Feed-Forward Equalization (FFE) may be applied to the recovered baseband signal to reverse ISI effects and achieve error free transmission.

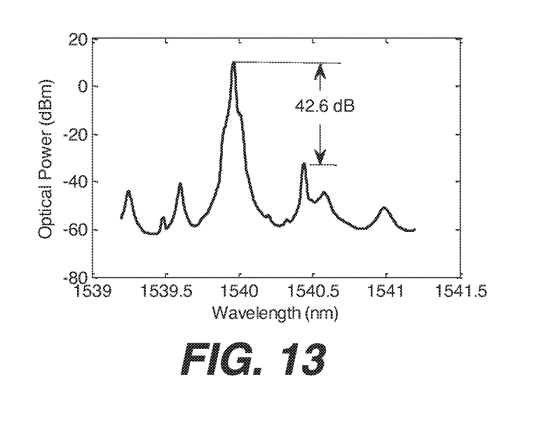

One important observation from FIG. 12 is that the sensitivity of the RoF system was very poor. The system required >0 dBm received optical power to meet the FEC threshold (1×10⁻³). This can be explained by considering the optical spectrum of the transmitted optical signal, shown in FIG. 13. FIG. 13 illustrates the optical spectrum of the transmitted OIL RoF system signal after direct VCSEL modulation with a 2 Gbps ASK signal at 60.5 GHz. From the optical spectrum, it is clear that the poor system sensitivity is due to the extremely high Carrier-to-Sideband power ratio (CSR). The difference in peak carrier optical power at about 1540 nm and peak sideband optical power at about 1540.5 nm is shown as 42.6 dB. The high CSR is caused by the large ML power, which is required for OIL, and is transmitted together with the VCSEL's modulated optical signal. Because of the poor sensitivity of the system, the maximum fiber transmission distances of this RoF system is limited by the SBS threshold, which limits the maximum fiber launch power at the HEU, and the fiber loss, which limits the received power. With this system, 10 km fiber transmission was achieved by limiting the launch optical power +10 dBm to avoid SBS.

### Example 2

### Transmitter with Bandpass Filtering/Equalization of VCSEL Output

Experimental Setup

To improve the sensitivity of the RoF system of Example 1 above, it was necessary to reduce the large CSR observed above. Thus, the experimental setup of FIG. 14 was constructed. The setup is generally arranged as a Head-End Unit 600 connected to a remote antenna unit 610 by optical fiber 620, which communicates with a 60 GHz wireless receiver 650. The arrangement included a pulse pattern generator PPG, arbitrary waveform generator AWG, low pass filter LPF, bias T B-T, band pass filter BPF, optical bandpass filters OBPF 1, OBPF 2 and OBPF 3, erbium doped fiber amplifiers EDFA, bit error rate tester (BERT) 660, and vector signal analyzer (VSA) 670. In this setup, a tunable filter was used to reduce the master carrier power. Given that the large CSR observed above was similar in value to the contrast ratio of typical tunable optical filters, placing the passband of a single optical bandpass filter (OBPF) (BW=0.25 nm) around the modulation sideband wavelength (so that the ML wavelength was outside the filter's passband) was sufficient to equalize the CSR. The filter bandwidth requirements were significantly relaxed by the sizeable frequency separation (0.5 nm) between the ML wavelength and the VCSEL sideband due to the high frequency of the 60 GHz carrier used. An EDFA preamp and a booster EDFA were then used to boost the equalized optical signal, followed by ASE noise filtering (0.6 nm, and 3 nm), as shown in FIG. 14. To realize wireless signal transmission, the signal exiting the LNA at the RAU was fed into a standard gain horn antenna (gain=23 dBi) and radiated into the air. After wireless transmission over 3 m, the signal was received by a 60 GHz wireless receiver using another standard gain horn antenna. The received signal was then amplified by a LNA (gain=22 dB), and filtered by a band pass filter (BPF; center frequency=60.5 GHz, bandwidth=7 GHz) before being down-converted to baseband, as shown in FIG. 14.

Impact of Equalization Filter

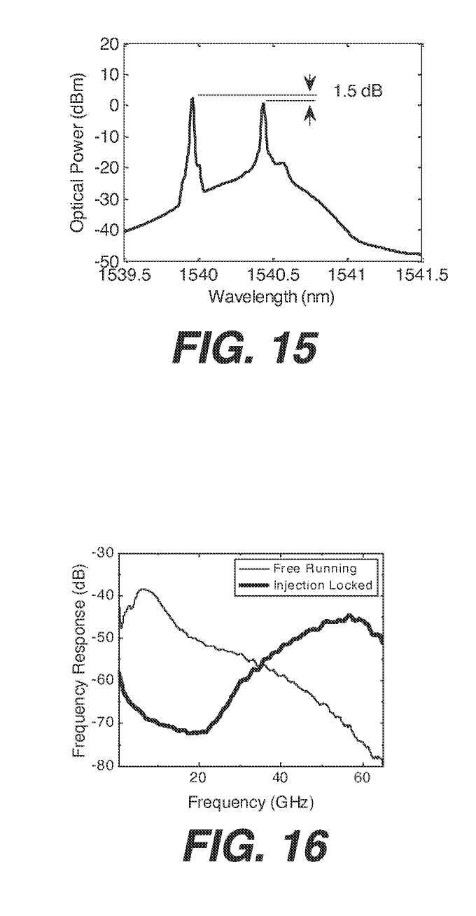

The impact of the equalization filter in the setup of FIG. 14 is shown in FIG. 15. FIG. 15 illustrates the optical spectrum of the carrier-sideband power ratio equalized signal with the OIL VCSEL modulated directly with a 2 Gbps ASK signal at 60.5 GHz. As shown in FIG. 15, the difference in the peak optical power between the master carrier at just below 1539.5 nm and the VCSEL's modulated sideband peak optical power at just below 1540 nm was reduced dramatically from 42.6 dB (shown in FIGS. 13) to 1.5 dB. Although the accurate definition of CSR is the ratio between the optical carrier and modulated sideband powers calculated in a specified bandwidth rather than the simple ratio between the peak powers, it is obvious from FIG. 15 that the CSR was significantly closer to optimal (˜0 dB for single carrier modulation) than it was without filtering. The frequency response of the equalized OIL-VCSEL with the same ML and VCSEL biasing conditions as those used to obtain FIG. 9 is shown in FIG. 16. FIG. 16 illustrates the frequency response of the carrier-to-sideband power ratio in an equalized RoF system employing direct modulation of OIL VCSEL. It can be seen that, compared to the un-equalized system, the frequency response was now heavily tilted in favor of the higher frequencies. Unlike in the un-equalized case, the response around the 60 GHz band was now much higher than at the lower frequencies below 30 GHz. This was due to the narrow-band optical BPF used, which tended to attenuate modulation sidebands at the lower modulation frequencies, since the filter's passband was tuned to the centre wavelength of the VCSEL's modulated sideband (i.e. optimized for 60 GHz modulation signals). FIG. 16 also shows that the equalized system had a relatively flat response (within 3 dB) over a wide frequency band equal to 18 GHz.

FIG. 16 also shows that the new frequency response at 60 GHz was now within 5 dBs of the frequency response of the free running VCSEL—signifying approximately 13 dB improvement in the response of the equalized system. This was a result of the post-CSR equalization amplification, which was only made possible by the CSR equalization. Apart from improving the system sensitivity, the higher frequency response also provided the critical system power budget, which was needed to overcome the high pathloss at 60 GHz in order to realize successful wireless signal transmission. The significantly improved frequency response also resulted in a higher received signal SNR, making it possible to use more spectrally efficient modulation formats such as QPSK, which require a higher SNR than ASK modulation.

Results for ASK Data Modulation

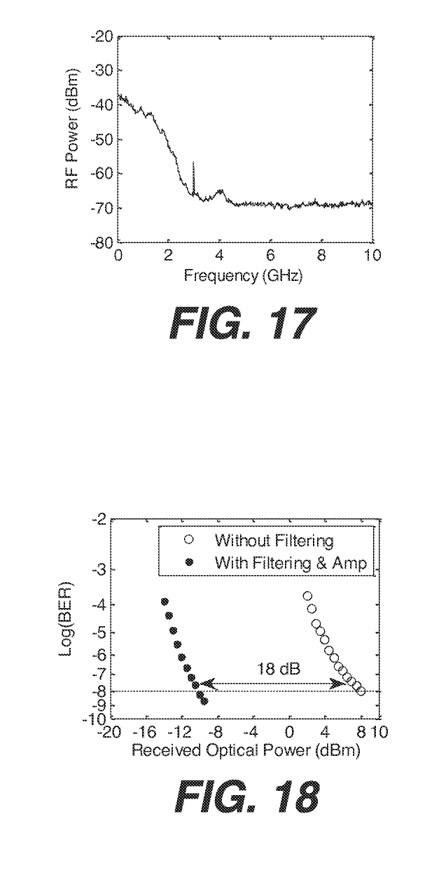

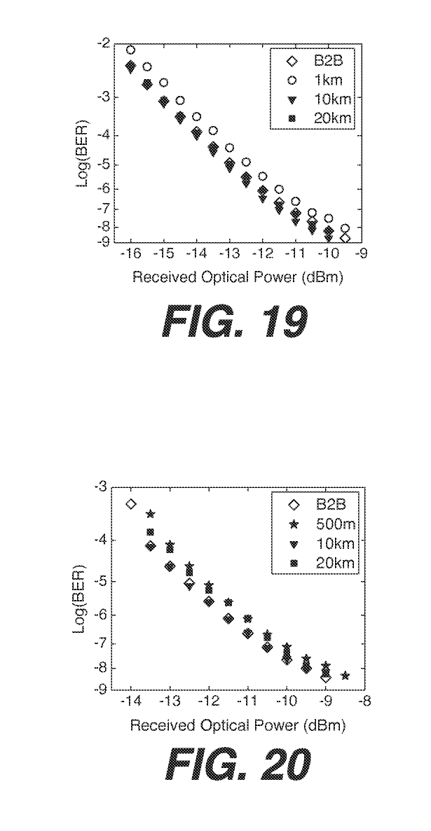

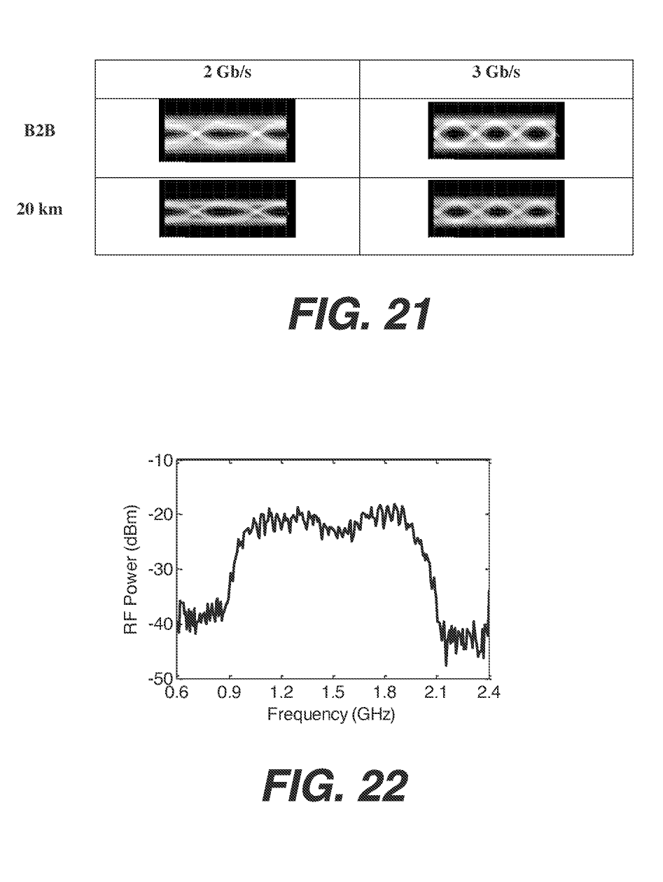

FIG. 17 illustrates the electrical spectrum of 3 Gbps PRBS-31 ASK signal down-converted after transmission over 20 km of standard single-mode fiber and 3 m wireless distance. The impact of the CSR equalization on the sensitivity of the ASK-modulated RoF system is shown in FIG. 18. FIG. 18 illustrates improvement in the receiver sensitivity of the RoF system due to carrier-to-sideband power ratio equalization for 2 Gbps ASK data modulation without fiber and wireless transmission. There was a very significant improvement in the system sensitivity by 18 dB for 2 Gbps ASK-data modulation, as shown. The improved sensitivity indicated that fiber transmission distances much longer than the 10 km achieved in the un-equalized RoF system would be feasible. This was confirmed by the BER performance results of the CSR-equalized RoF system shown in FIG. 19 and FIG. 20 for 2 Gbps and 3 Gbps ASK data transmission, respectively. In both cases, 20 km fiber transmission distance was achieved with very good sensitivities and negligible power penalties with respect to the B2B system performance. Referring to FIG. 19, for 2 Gbps ASK data (PRBS −31) modulation and 20km fiber transmission distance, the sensitivities were −14.0 dBm and −10.5 dBm at the BERs of 1×10⁻⁴ and 1×10⁻⁸, respectively. Referring to FIG. 20, for 3 Gbps, the corresponding sensitivities were −13.0 dBm and −9.5 dBm, respectively. Therefore, the difference in the system sensitivities at the two data-rates was 1 dB. FIG. 19 and FIG. 20 show some error flooring, but at much lower BERs closer to error-free transmission (1×10⁻⁹). In both cases, the fluctuation in sensitivity for the different fiber transmission distances was less than 0.5 dB, which was attributed to the interaction between signal chirp and fiber dispersion. The eye diagrams of received ASK data before and after transmission over 20 km of standard single-mode fiber and 3 m wireless distance are shown in FIG. 21. Clearly open eye diagrams were observed after 20 km of fiber transmission as shown in FIG. 21.

Results for QPSK Data Modulation

To test the performance of the CSR-equalized OIL RoF system with complex multi-level modulation formats, the PPG in FIG. 14 was replaced with an Arbitrary Waveform Generator (AWG), which was used to generate wideband QPSK signals. After transmission over fiber and 3 m wireless distance, the recovered signal was analyzed by a Vector Signal Analyzer. FIG. 22 shows the spectrum of the recovered 2 Gbps QPSK signal (PRBS-9) modulated on a 1.5 GHz sub-carrier. The received optical power was −8 dBm with the corresponding Error Vector Magnitude (EVM) and SNR equal to 15.0% and 16.4 dB, respectively. The small dip (˜2 dB) observed in the centre of the spectrum comes from the frequency response of the end-to-end RoF link. Because of the wide spectrum of the transmitted signal (˜1 GHz), DSB modulation/demodulation was used in the 60 GHz up/down-converters. Using SSB modulation in the electrical up/down-converters would result in a less flattened spectrum, and, consequently ISI, which would require equalization (e.g. FFE) to achieve good system performance.

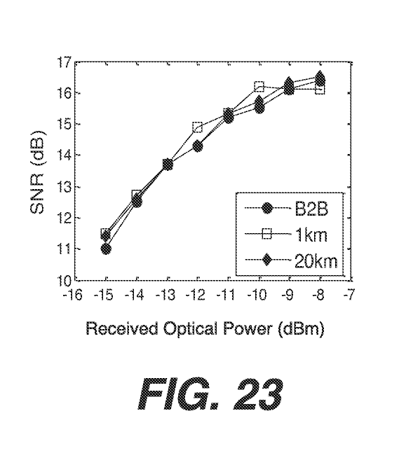

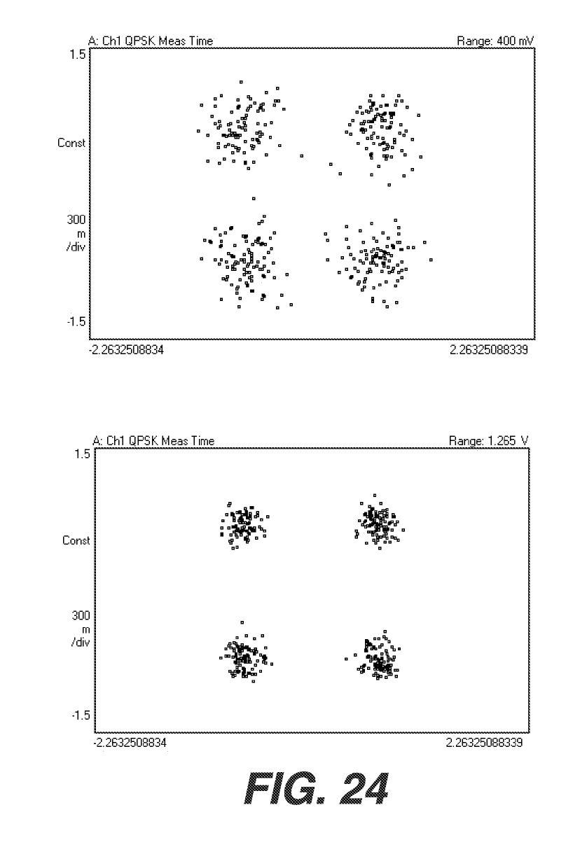

Measurement results for fiber transmission experiments are summarized in FIG. 23, which illustrates measured SNR performance of the 60 GHz RoF system modulated with 2 Gbps QPSK data after transmission over up to 20 km of standard single-mode fiber and 3 m wireless distance. As was the case in the ASK experiments, no dispersion penalty was observed for QPSK modulated data over fiber transmission distances up-to 20 km (including 3 m wireless distance), as shown. This was due to the optical SSB modulation employed, which in the CSR equalized case was aided by the filtering. Very clear constellation diagrams were obtained as shown in FIG. 24. The constellation diagrams are of recovered 2 Gbps QPSK signal of the RoF system after transmission over 20 km of standard single-mode fiber and 3 m wireless distance. EVM was 27% and 15% at −15 dBm (top) and −8 dBm (bottom) received optical power, respectively.

As shown in FIG. 23, the sensitivity of the 2 Gbps QPSK-modulated system at the BER of 1×10⁻³ corresponding to a SNR of 10 dB was less than −15 dBm. This is similar to the sensitivity of the ASK modulated system at the same data-rate. When a lower data-rate of 1 Gbps was used, the measured SNR was much higher (i.e. 20.7 dB at −10.0 dBm received optical power, and 20 km fiber transmission) and the sensitivity was much higher. These results for QPSK transmission were made possible by the improved link efficiency due to CSR equalization employed. These results demonstrate that the CSR-equalized RoF system can support fiber lengths much longer than 20 km and much higher data-rates through the use of much higher order modulation formats such as 8-QAM, and 16-QAM, which are more spectrally efficient than ASK and QPSK modulation formats.

The devices and methods disclosed herein are advantageous in that they enable the optical power ratio between the carrier signal component and the sideband signal component to be adjusted independently of the injection ratio (ratio of the optical power of the master laser to the optical power of the slave laser). As a result, the optical power ratio between the carrier signal component and the sideband signal component can be optimized while also maintaining an optimized injection ratio. Furthermore, the devices and methods provide higher optical link efficiency by providing higher received RF power, which enables higher transmitted wireless power for a given transmitted optical power. Higher bit rates are also enabled because equalizing the optical power ratio between the carrier signal component and the sideband signal component results in a higher SNR, which makes it possible to employ spectrally efficient complex modulation formats (e.g., QPSK, quadrature amplitude modulation (xQAM), optical frequency-division multiplexing (OFDM)). Additionally, by reducing the carrier signal component power through filtering, the devices significantly reduce the power launched into the transmission channel to well below the stimulated Brillouin scattering (SBS) threshold of long fiber spans. Furthermore, by attenuating the carrier signal component, it is possible to use amplifiers to extend the reach of the optical link between the device and components receiving transmissions from the device. Longer wireless transmission distances are also possible due to the combination of high link efficiency, high generated RF power, and high RF signal SNR.

The devices and methods disclosed herein also provide a low cost, low complexity and reliable solution for obtaining the above benefits. For example, in the embodiment of FIGS. 1 and 2, the bandpass filter is inexpensive and less sensitive to environmental conditions, such as temperature, in comparison to the notch filters (e.g., fiber Bragg gating (FBG) filters) and other narrow band filters commonly used in conventional optical transmission devices. In the embodiments of FIGS. 4 and 5, cost and complexity are reduced by employing a single optical element to perform the functions of routing the optical signals and optimizing the optical power ratio between the carrier signal component and the sideband signal component. The embodiment of FIG. 6 reduces the cost of a system employing multiple transmitters by using a single master laser to lock multiple slave lasers without having to split the power from the master laser.

It will be apparent to those skilled in the art that various modifications and variations can be made without departing from the spirit or scope of the invention.

What is claimed is:

1. An optical transmission device comprising:
a master laser configured to generate a master signal;
a VCSEL configured for optical injection locking by the master laser, and configured to generate a VCSEL output signal comprising a carrier component and a modulated sideband component; and
an equalizer unit configured to receive the VCSEL output signal and output an equalized output signal having a reduced ratio of carrier component power to modulated sideband component power in comparison to the VCSEL output signal.

2. The optical transmission device of claim 1, wherein:
the equalizer unit comprises an optical filter configured to attenuate the first carrier component to output the equalized output signal, the optical filter comprising a bandpass filter, a low-pass filter or a band-stop filter; and
the optical transmission device comprises an optical circulator coupled to the master laser and the VCSEL, wherein the optical circulator is configured to route the master signal to the VCSEL and route the VCSEL output signal to the optical filter.

3. The optical transmission device of claim 2, comprising an optical amplifier configured to amplify the equalized output signal.

4. The optical transmission device of claim 1, wherein:
the equalizer unit comprises a first three-port optical filter, the first three-port optical filter being configured to
receive the VCSEL output signal from the VCSEL,
separate the carrier component and the modulated sideband component, and
separately transmit the carrier component and the modulated sideband component; and
the optical transmission device comprises a first optical circulator configured to route the master signal to the first VCSEL and route the VCSEL output signal to the first three-port optical filter.

5. The optical transmission device of claim 4, wherein the equalizer unit comprises:
a variable optical attenuator configured to receive the carrier component from the first three-port optical filter and attenuate the carrier component to form an attenuated carrier component; and
a second three-port optical filter or a three-port optical power coupler, wherein the second three-port optical filter or three-port optical power coupler is configured to combine the attenuated carrier component and the modulated sideband component to output the equalized output signal.

6. The optical transmission device of claim 4, wherein the equalizer unit comprises:
an optical amplifier configured to receive the modulated sideband component from the first three-port optical filter and amplify the modulated sideband component to form an amplified sideband component; and
a second three-port optical filter or a three-port optical power coupler, wherein the second three-port optical filter or three-port optical power coupler is configured to combine the carrier component and the amplified sideband component to output the equalized output signal.

7. The optical transmission device of claim 1, wherein the equalizer unit comprises a three-port optical filter configured to:
receive the master signal;
route the master signal to the VCSEL;
receive the VCSEL output signal from the VCSEL;
reflect or absorb a first portion of the carrier component; and
output the modulated sideband component and a second portion of the carrier component to form the equalized output signal.

8. The optical transmission device of claim 7, comprising an optical isolator configured to:
receive the master signal from the master laser;
transmit the master signal to the three-port optical filter; and
absorb the first portion of the carrier component.

9. The optical transmission device of claim 1, wherein the equalizer unit comprises an optical amplifier configured to provide a wavelength-dependent optical gain or a wavelength-dependent optical loss, and wherein the amplifier is configured to receive the VCSEL output signal and either amplify the modulated sideband component or attenuate the carrier component to output the equalized output signal.

10. An optical transmission device, comprising:
a master laser;
a first VCSEL configured for optical injection locking by the master laser, and configured to generate a first VCSEL output signal comprising a first carrier component and a first modulated sideband component;
a first three-port optical filter configured to
receive the first VCSEL output signal from the first VCSEL,
separate the first carrier component and the first modulated sideband component, and
separately transmit the first carrier component and the first modulated sideband component; and
a second VCSEL configured for optical injection locking by the master laser by receiving the first carrier component from the first three-port optical filter, and configured to generate a second VCSEL output signal comprising a second carrier component and a second modulated sideband component;
a second three-port optical filter configured to
receive the second VCSEL output signal from the second VCSEL,
separate the second carrier component and the second modulated sideband component, and
separately transmit the second carrier component and the second modulated sideband component.

11. The optical transmission device of claim 10, comprising:
a first optical circulator configured to route a master signal from the master laser to the first VCSEL and route the first VCSEL output signal to the first three-port optical filter; and
a second optical circulator configured to route the first carrier component to the second VCSEL and route the second VCSEL output signal to the second three-port optical filter.

12. The optical transmission device of claim 1, wherein the equalizer unit comprises an optical filter configured to attenuate the carrier component without substantially attenuating the modulation sideband component.

13. An optical transmission method comprising:
injection locking a VCSEL by a master laser;
operating the VCSEL to generate a VCSEL output signal comprising a carrier component and a modulated sideband component;
transmitting the VCSEL output signal to an equalizer unit;
forming an equalized output signal in the equalizer unit, wherein the equalized output signal comprises a reduced ratio of carrier component power to modulated sideband component power in comparison to the VCSEL output signal; and
outputting the equalized output signal.

14. The method of claim 13, comprising:
routing a master signal from the master laser to the VCSEL via an optical circulator;
routing the VCSEL output signal from the VCSEL to an optical filter in the equalizer unit via the optical circulator, wherein the optical filter comprises a bandpass filter, a low-pass filter or a band-stop filter;
attenuating the carrier component in the optical filter to form the equalized output signal; and
outputting the equalized output signal from the optical filter.

15. The method of claim 14, comprising amplifying the equalized output signal with an optical amplifier.

16. The method of claim 13, comprising:
routing the master signal to the VCSEL via a first optical circulator;
routing the VCSEL output signal to a first three-port optical filter in the equalizer unit via a first optical circulator;
separating the carrier component and the modulated sideband component with the first three-port optical filter; and
separately transmitting the carrier component and the modulated sideband component from the first three-port optical filter.

17. The method of claim 16, comprising:
passing the carrier component through a variable optical attenuator in the equalizer unit to form an attenuated carrier component;
transmitting the attenuated carrier component to a second three-port optical filter or a three-port optical power coupler in the equalizer unit;
combining the attenuated carrier component and the modulated sideband component in the second three-port optical filter or three-port optical power coupler to form the equalized output signal; and
outputting the equalized output signal from the second three-port optical filter or three-port optical power coupler.

18. The method of claim 16, comprising:
transmitting the carrier component to a second three-port optical filter or a three-port optical power coupler in the equalizer unit;
amplifying the modulated sideband component in the equalizer unit with an optical amplifier to form an amplified sideband component;
transmitting the amplified sideband component to the second three-port optical filter or three-port optical power coupler;
combining the carrier component and the amplified sideband component in the second three-port optical filter or three-port optical power coupler to form the equalized output signal; and
outputting the equalized output signal from the second three-port optical filter or three-port optical power coupler.

19. The method of claim 13, comprising:
routing a master signal from the master laser to the VCSEL via a three-port optical filter;
routing the VCSEL output signal to the three-port optical filter;
reflecting or absorbing a first portion of the carrier component in the three-port optical filter; and
outputting the modulated sideband component and a second portion of the carrier component from the three-port optical filter to form the equalized output signal.

20. The method of claim 19, wherein routing the master signal from the master laser to the VCSEL comprises routing the master signal through an optical isolator, and wherein the method comprises:
directing the first portion of the carrier component to the optical isolator; and
absorbing the first portion of the carrier component in the optical isolator.

21. The method of claim 13, comprising:
routing the VCSEL output signal to an optical amplifier in the equalizer unit, wherein the optical amplifier is configured to provide a wavelength-dependent optical gain or a wavelength-dependent optical loss;
amplifying the modulated sideband component or attenuating the carrier component in the optical amplifier to form the equalized output signal; and
outputting the equalized output signal from the optical amplifier.

22. An optical transmission method comprising:
injection locking a first VCSEL by a master laser;
operating the first VCSEL to generate a first VCSEL output signal comprising a first carrier component and a first modulated sideband component;
routing the first VCSEL output signal to a first three-port optical filter;
separating the first carrier component and the first modulated sideband component with the first three-port optical filter;
separately transmitting the first carrier component and the first modulated sideband component from the first three-port optical filter;
injection locking a second VCSEL using the first carrier component;
operating the second VCSEL to generate a second VCSEL output signal comprising a second carrier component and a second modulated sideband component;
routing the second VCSEL output signal to a second three-port optical filter;
separating the second carrier component and the second modulated sideband component with the second three-port optical filter; and
separately transmitting the second carrier component and the second modulated sideband component from the second three-port optical filter.

23. The method of claim 22, wherein:
injection locking the first VCSEL by a master laser comprises routing a master signal from the master laser through a first optical circulator to the first VCSEL;
routing the first VCSEL output signal to the first three-port optical filter comprises routing the first VCSEL output signal through the first optical circulator;
injection locking the second VCSEL using the first carrier component comprises routing the first carrier component through a second optical circulator to the second VCSEL; and
routing the second VCSEL output signal to the second three-port optical filter comprises routing the second VCSEL output signal through the second optical circulator.

24. The method of claim 13, comprising:
routing the VCSEL output signal to an optical filter in the equalizer unit;
forming the equalized output signal by attenuating the carrier component in the optical filter without substantially attenuating the modulation sideband component.
